(19) United States
(12) Patent Application Publication
(10) Pub. No.: US 2025/0311538 A1
(43) Pub. Date: Oct. 2, 2025

(54) LIGHT EMITTING ELEMENT AND DISPLAY DEVICE INCLUDING THE SAME

(71) Applicant: Samsung Display Co., LTD., Yongin-si (KR)

(72) Inventors: Il Ha SONG, Yongin-si (KR); Nam Su KANG, Yongin-si (KR)

(21) Appl. No.: 18/890,379

(22) Filed: Sep. 19, 2024

(30) Foreign Application Priority Data
Apr. 1, 2024 (KR) 10-2024-0044096

(51) Int. Cl. H10K 50/15; H10K 59/80; H10K 101/30; H10K 102/00

(52) U.S. Cl. CPC H10K 50/15; H10K 59/8051; H10K 2101/30; H10K 2102/351

(57) ABSTRACT

A light emitting element includes: an anode, a hole injection layer disposed on the anode, a hole transport layer disposed on the hole injection layer, a light emitting layer disposed on the hole transport layer, and a cathode disposed on the light emitting layer. The hole injection layer includes a triazine compound or a pyrimidine compound.

### CROSS-REFERENCE TO RELATED APPLICATION

The present application claims priority to and the benefit of Korean Patent Application No. 10-2024-0044096, filed on Apr. 1, 2024, in the Korean Intellectual Property, the entire content of which is incorporated herein by reference.

### BACKGROUND

### 1. Field

The present disclosure relates to a light emitting element and a display device including the light emitting element.

### 2. Description of the Related Art

As information technology develops (advances), display devices are becoming more prevalent (increasingly used) as a tool or means for communicating (conveying) information to users. Such display devices include (often feature) display panels like (such as) a liquid crystal displays (LCDs) or an organic light emitting diode (OLED) displays.

The above information disclosed in this Background section is only for enhancement of understanding of the background and therefore the information discussed in this Background section does not necessarily constitute prior art.

### SUMMARY

Aspects of one or more embodiments of the present disclosure include a light emitting element with an increased (or improved) hole injection characteristic and a display device with increased (or improved) color reproducibility and display characteristic.

Additional aspects of embodiments will be set forth in part in the description, which follows and, in part, will be apparent from the description, or may be learned by practice of the presented embodiments of the disclosure.

According to one or more embodiments of the present disclosure, a light emitting element includes: an anode, a hole injection layer arranged on the anode, a hole transport layer arranged on the hole injection layer, a light emitting layer arranged on the hole transport layer, and a cathode arranged on the light emitting layer. According to one or more embodiments, the hole injection layer may include a triazine compound or a pyrimidine compound.

According to one or more embodiments, the hole injection layer may contact the anode.

According to one or more embodiments, a thickness of the hole injection layer may be about 0.5 angstroms to 50 angstroms.

According to one or more embodiments, a dipole moment of the hole injection layer may be about 1 Debye to 6 Debye.

According to one or more embodiments, a highest occupied molecular orbital (HOMO) energy level of the hole injection layer may be about −6.3 eV to −5 eV.

According to one or more embodiments, the hole injection layer may be a single layer (e.g., a continuous layer over the light emitting element).

According to one or more embodiments, the anode is to provide charge carriers, such as to provide a first hole and a second hole, and an energy barrier is between the anode and the hole injection layer, the first hole may (e.g., have an energy higher than the energy barrier) cross over the energy barrier and may be transmitted to the hole injection layer, and the second hole may (e.g., have an energy lower than the energy barrier) pass through the energy barrier and may be transmitted to the hole injection layer. To put it in other words, the first hole may be injected into the hole injection layer through a first path. For example, the first hole (e.g., when heated) may have an energy higher than that of the barrier, allowing it to be injected into the hole injection layer beyond the barrier. This injection may occur by thermionic emission or, in some embodiments, by forming a charge transfer complex (CT complex). Conversely, the second hole may be injected into the hole injection layer through a second path. For example, the second hole may have an energy lower than that of the barrier, but it can still “pass through” the barrier and be injected into the hole injection layer by quantum tunneling.

According to one or more embodiments, the light emitting element may further include an auxiliary layer arranged between the hole transport layer and the light emitting layer.

According to one or more embodiments, the light emitting element may further include a buffer layer arranged on the light emitting layer, an electron transport layer arranged on the buffer layer, and an electron injection layer arranged between the cathode and the electron transport layer.

According to one or more embodiments of the present disclosure, a display device includes: a substrate, a pixel circuit layer arranged on the substrate, and a light emitting element provided on the pixel circuit layer. According to one or more embodiments, the light emitting element may include an anode arranged on the pixel circuit layer, a hole injection layer arranged on the anode, a hole transport layer arranged on the hole injection layer, a light emitting layer arranged on the hole transport layer, and a cathode arranged on the light emitting layer, and the hole injection layer may include a triazine compound or a pyrimidine compound.

According to one or more embodiments, the substrate may be a glass substrate, and the anode may be Ag/ITO (e.g., a two layer structure of Ag/ITO).

According to one or more embodiments, the substrate may be a silicon substrate, and the anode may be Al/TiN (e.g., a two layer structure of Al/TiN).

According to one or more embodiments, the hole injection layer may contact the anode.

According to one or more embodiments, a thickness of the hole injection layer may be about 0.5 angstroms to 50 angstroms.

According to one or more embodiments, a dipole moment of the hole injection layer may be about 1 Debye to 6 Debye.

According to one or more embodiments, a highest occupied molecular orbital (HOMO)energy level of the hole injection layer may be about −6.3 eV to −5 eV.

According to one or more embodiments, the hole injection layer may be a single layer (e.g., a continuous layer over the substrate).

According to one or more embodiments, the anode is to provide a first hole and a second hole, and an energy barrier is between the anode and the hole injection layer, the first hole may cross over the energy barrier and may be transmitted to the hole injection layer, and the second hole may pass through the energy barrier and may be transmitted to the hole injection layer. For example, the first hole may cross the barrier and be injected into the hole injection layer. When heated, the first hole may gain energy higher than that of the barrier, enabling it to be injected into the hole injection layer beyond the barrier. Conversely, the second hole may have an energy lower than that of the barrier, but it can still pass through the barrier and be injected into the hole injection layer.

According to one or more embodiments, the display device may further include an auxiliary layer arranged between the hole transport layer and the light emitting layer.

According to one or more embodiments, the display device may further include a buffer layer arranged on the light emitting layer, an electron transport layer arranged on the buffer layer, and an electron injection layer arranged between the cathode and the electron transport layer.

Details of one or more suitable embodiments are included in the detailed descriptions and drawings.

### BRIEF DESCRIPTION OF DRAWINGS

The above and other aspects and features of embodiments according to the present disclosure will become more apparent by describing, in further detail, aspects of one or more embodiments thereof with reference to the accompanying drawings, in which:

FIG. 1 is a block diagram of a display device according to one or more embodiments.

FIG. 2 is a block diagram of a sub-pixel according to one or more embodiments.

FIG. 3 is a circuit diagram of a sub-pixel according to one or more embodiments.

FIG. 4 is a plan view of a display panel according to one or more embodiments.

FIG. 5 is a schematic illustration of a pixel according to one or more embodiments.

FIG. 6 is a diagram showing a characteristic of a hole injection layer according to one or more embodiments.

FIG. 7 is a cross-sectional view of a pixel according to one or more embodiments.

FIG. 8 is a block diagram of a display system according to one or more embodiments.

FIG. 9 is a perspective view of an application example of a display system of FIG. 8 according to one or more embodiments.

FIG. 10 is a diagram of a head-mounted display device of FIG. 9 that is worn on a user according to one or more embodiments.

### DETAILED DESCRIPTION

Aspects of one or more embodiments of the present disclosure now will be described more fully hereinafter with reference to the accompanying drawings, in which one or more suitable embodiments thereof are shown. The present disclosure may, however, be embodied in many different forms, and should not be construed as limited to the embodiments described herein. Rather, these embodiments are provided so that this disclosure will be more thorough and more complete, and will more fully convey the scope of embodiments according to the present disclosure to those skilled in the art.

It will be understood that if (e.g., when) an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, if (e.g., when) a first element is described as being “coupled” or “connected” to a second element, the first element may be directly coupled or connected to the second element or the first element may be indirectly coupled or connected to the second element via one or more intervening elements.

In the drawings, dimensions of the one or more suitable elements, layers, and/or the like, may be exaggerated for clarity of illustration. The same reference numerals designate the same elements. As used herein, the term “and/or” includes any and all combinations of one or more of the associated listed items. Further, the use of “may” if (e.g., when) describing embodiments of the present disclosure relates to “one or more embodiments of the present disclosure.” Expressions, such as “at least one of” and “any one of,” if (e.g., when) preceding a list of elements, modify the entire list of elements and do not modify the individual elements of the list. For example, the expression “at least one of a, b, or c” indicates only a, only b, only c, both (e.g., simultaneously) a and b, both (e.g., simultaneously) a and c, both (e.g., simultaneously) b and c, all of a, b, and c, or combination of a, b, and/or c. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, and/or the like, may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and/or the like, may be used herein for ease of description to describe one element or feature's relationship to another element(s) or feature(s) as illustrated in the drawings. It will be understood that the spatially relative terms are intended to encompass different orientations of the device in use or operation in addition to the orientation depicted in the drawings. For example, if the device in the drawings is turned over, elements described as “below” or “beneath” other elements or features would then be oriented “above” or “over” the other elements or features. Thus, the term “below” may encompass both (e.g., simultaneously) an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” if (e.g., when) used in this specification, specify the presence of stated features, integers, steps, operations, elements, components, and/or groups but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, aspects of one or more embodiments of the present disclosure will be described in more detail with reference to the accompanying drawings.

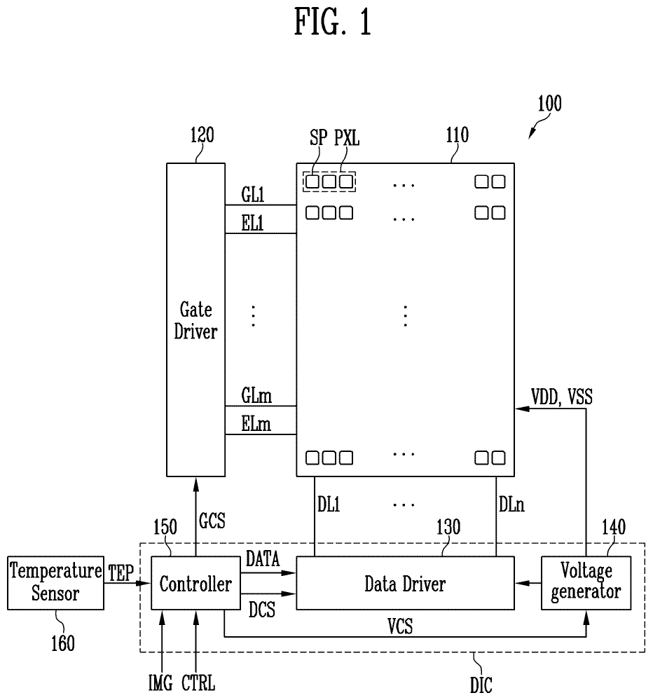

FIG. 1 is a block diagram of a display device according to one or more embodiments.

Referring to FIG. 1, the display device 100 may include a display panel 110, a gate driver 120, a data driver 130, a voltage generator 140, and a controller 150.

The display panel 110 includes sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

Each of the sub-pixels SP may include at least one light emitting element configured to generate light. Accordingly, each of the sub-pixels SP may generate light of a specific color such as red, green, blue, cyan, magenta, or yellow. Two or more sub-pixels among (e.g., selected from among) the sub-pixels SP may configure (e.g., form) one pixel PXL. For example, as shown in FIG. 1, three sub-pixels may configure one pixel PXL.

The gate driver 120 is connected to the sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal indicating a start (e.g., beginning) of each frame, a horizontal synchronization signal for outputting the gate signals in synchronization with a timing at which data signals are applied (e.g., the timing of data signal application), and/or the like.

In one or more embodiments, first to m-th emission control lines EL1 to ELm connected to the sub-pixels SP of the row direction may be further provided. In this case, the gate driver 120 may include an emission control driver configured to control the first to m-th emission control lines EL1 to Elm, and the emission control driver may operate under control of (e.g., may be controlled by) the controller 150.

The gate driver 120 may be arranged on one side of the display panel 110. However, embodiments are not limited thereto. For example, the gate driver 120 may be divided into two or more physically and/or logically divided drivers, and these drivers may be arranged on one side of the display panel 110 and another side of the display panel 110 (opposite to the one side). As described above, the gate driver 120 may be arranged around the display panel 110 in one or more suitable shapes according to one or more embodiments.

The data driver 130 is connected to the sub-pixels SP arranged in a column direction through the first to n-th data lines DL1 to DLn. The data driver 130 receives image data DATA and a data control signal DCS from the controller 150. The data driver 130 operates in response to the data control signal DCS. In one or more embodiments, the data control signal DCS may include a source start pulse, a source shift clock, a source output enable signal, and/or the like.

The data driver 130 may apply data signals having grayscale voltages corresponding to the image data DATA to the first to n-th data lines DL1 to DLn using voltages from the voltage generator 140. When the gate signal is applied to each of the first to m-th gate lines GL1 to GLm, the data signals corresponding to the image data DATA may be applied to the first to n-th data lines DL1 to DLm. Accordingly, the corresponding sub-pixels SP may generate light corresponding to the data signals. Accordingly, an image is displayed on the display panel 110.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display device 100. For example, the voltage generator 140 may be configured to generate the plurality of voltages by receiving an input voltage from a source outside of the display device 100, adjusting the received voltage, and regulating the adjusted voltage.

The voltage generator 140 may generate a first power voltage VDD and a second power voltage VSS, and the generated first and second power voltages VDD and VSS may be provided to the sub-pixels SP. The first power voltage VDD may have a relatively higher voltage level, and the second power voltage VSS may have a voltage level lower than that of the first power voltage VDD. In one or more embodiments, the first power voltage VDD or the second power voltage VSS may be provided by an external device of the display device 100.

In addition, the voltage generator 140 may generate one or more suitable voltages. For example, the voltage generator 140 may generate an initialization voltage applied to the sub-pixels SP. For example, during a sensing operation for sensing electrical characteristics of transistors and/or light emitting elements of the sub-pixels SP, a set or predetermined reference voltage may be applied to the first to n-th data lines DL1 to DLn, and such a reference voltage may be generated by the voltage generator 140.

The controller 150 controls overall operations of the display device 100. The controller 150 receives input image data IMG and a control signal CTRL for controlling display of the input image data IMG from the outside. The controller 150 may provide the gate control signal GCS, the data control signal DCS, and the voltage control signal VCS in response to the control signal CTRL.

The controller 150 may convert the input image data IMG so that the input image data IMG is (e.g., becomes) suitable for the display device 100 or the display panel 110 and then output the image data DATA. In one or more embodiments, the controller 150 may output the image data DATA by aligning the input image data IMG so that the input image data IMG is suitable for the sub-pixels SP of a row unit.

Two or more components from among (e.g., selected from among) the data driver 130, the voltage generator 140, and the controller 150 may be mounted on one integrated circuit. As shown in FIG. 1, the data driver 130, the voltage generator 140, and the controller 150 may be included in a driver integrated circuit DIC. In this case, the data driver 130, the voltage generator 140, and the controller 150 may be functionally divided components in one driver integrated circuit DIC. In one or more embodiments, at least one selected from among the data driver 130, the voltage generator 140, and the controller 150 may be provided as a component distinguished (e.g., separated) from the driver integrated circuit DIC.

The display device 100 may include at least one temperature sensor 160. The temperature sensor 160 is configured to sense a temperature around the temperature sensor 160 and generate temperature data TEP indicating the sensed temperature. In one or more embodiments, the temperature sensor 160 may be arranged adjacent to the display panel 110 and/or the driver integrated circuit DIC.

The controller 150 may control one or more suitable operations of the display device 100 in response to the temperature data TEP. In one or more embodiments, the controller 150 may adjust a luminance of the image output from the display panel 110 in response to the temperature data TEP. For example, the controller 150 may control the data signals and the first and second power voltages VDD and VSS by controlling components such as the data driver 130 and/or the voltage generator 140.

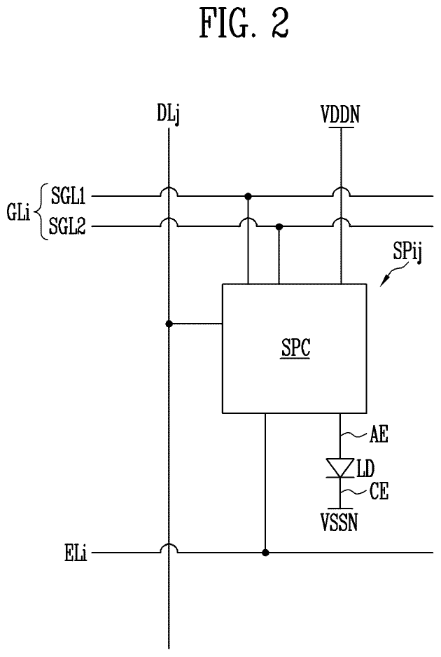

FIG. 2 is a block diagram of a sub-pixel according to one or more embodiments. In FIG. 2, among the sub-pixels SP of FIG. 1, a sub-pixel SPij arranged in an i-th row (i is an integer greater than or equal to 1 and less than or equal to m) and a j-th column (j is an integer greater than or equal to 1 and less than or equal to n) is shown as an example.

Referring to FIG. 2, the sub-pixel SPij may include a sub-pixel circuit SPC and a light emitting element LD.

The light emitting element LD is connected between a first power voltage node VDDN and a second power voltage node VSSN. In one or more embodiments, the first power voltage node VDDN is a node that transmits the first power voltage VDD of FIG. 1, and the second power voltage node VSSN is a node that transmits the second power voltage VSS of FIG. 1.

An anode AE of the light emitting element LD may be connected to the first power voltage node VDDN through the sub-pixel circuit SPC, and a cathode CE of the light emitting element LD may be connected to the second power voltage node VSSN. For example, the anode AE of the light emitting element LD may be connected to the first power voltage node VDDN through one or more transistors included in the sub-pixel circuit SPC.

The sub-pixel circuit SPC may be connected to an i-th gate line GLi among (e.g., selected from among) the first to m-th gate lines GL1 to GLm of FIG. 1, an i-th emission control line ELi among (e.g., selected from among) the first to m-th emission control lines EL1 to ELm of FIG. 1, and a j-th data line DLj among (e.g., selected from among) the first to n-th data lines DL1 to DLn of FIG. 1. That is, the sub-pixel circuit (SPC) may be connected to the i-th gate line (GLi), the i-th emission control line (ELi), and the j-th data line (DLj). The sub-pixel circuit SPC is configured to control the light emitting element LD according to signals received through such (the three) signal lines.

The sub-pixel circuit SPC may operate in response to a gate signal received through the i-th gate line GLi. The i-th gate line GLi may include one or more sub gate lines. In one or more embodiments, as shown in FIG. 2, the i-th gate line GLi may include first and second sub gate lines SGL1 and SGL2. The sub-pixel circuit SPC may operate in response to gate signals received through the first and second sub gate lines SGL1 and SGL2. As described above, if (e.g., when) the i-th gate line GLi includes two or more sub gate lines, the sub-pixel circuit SPC may operate in response to gate signals received through the corresponding sub gate lines.

The sub-pixel circuit SPC may operate in response to an emission control signal received through the i-th emission control line ELi. In one or more embodiments, the i-th emission control line ELi may include one or more sub emission control lines. When the i-th emission control line ELi includes two or more sub emission control lines, the sub-pixel circuit SPC may operate in response to emission control signals received through the corresponding sub emission control lines.

The sub-pixel circuit SPC may receive a data signal through the j-th data line DLj. The sub-pixel circuit SPC may store a voltage corresponding to the data signal in response to at least one of (e.g., selected from among) the gate signals received through the first and second sub gate lines SGL1 and SGL2. The sub-pixel circuit SPC may adjust a current flowing from the first power voltage node VDDN to the second power voltage node VSSN through the light emitting element LD according to the stored voltage, in response the emission control signal received through the i-th emission control line ELi. Accordingly, the light emitting element LD may generate light of a luminance corresponding to the data signal.

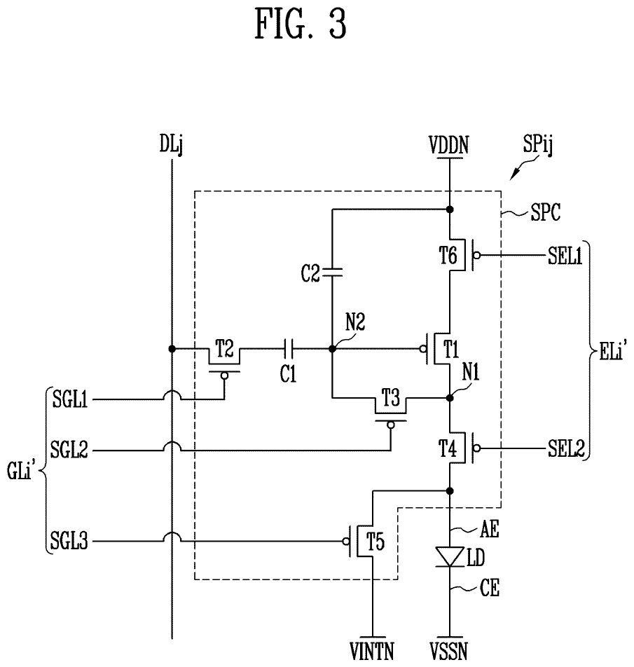

FIG. 3 is a circuit diagram of a sub-pixel according to one or more embodiments.

Referring to FIG. 3, the sub-pixel SPij may include a sub-pixel circuit SPC and a light emitting element LD.

The sub-pixel circuit SPC may be connected to an i-th gate line GLi′, an i-th emission control line ELi′, and the j-th data line DLj. Compared to the i-th gate line GLi of FIG. 2, the i-th gate line GLi′ may further include a third sub gate line SGL3. Compared to the i-th emission control line ELi of FIG. 2, the i-th emission control line ELi′ may include a first sub emission control line SEL1 and a second sub emission control line SEL2.

The sub-pixel circuit SPC may include first to sixth transistors T1 to T6, and first and second capacitors C1 and C2.

The first transistor T1 is connected between the first power voltage node VDDN and a first node N1. A gate of the first transistor T1 may be connected to a second node N2, and thus the first transistor T1 may be turned on according to a voltage level of the second node N2. The first transistor T1 may be referred to as a driving transistor.

The second transistor T2 is connected between the j-th data line DLj and the second node N2. A gate of the second transistor T2 may be connected to the first sub gate line SGL1, and thus the second transistor T2 may be turned on in response to a gate signal of the first sub gate line SGL1. The second transistor T2 may be referred to as a switching transistor.

The third transistor T3 is connected between the first node N1 and the second node N2. A gate of the third transistor T3 may be connected to the second sub gate line SGL2, and thus the third transistor T3 may be turned on in response to a gate signal of the second sub gate line SGL2.

The fourth transistor T4 is connected between the first node N1 and the anode AE of the light emitting element LD. A gate of the fourth transistor T4 may be connected to the second sub emission control line SEL2, and thus the fourth transistor T4 may be turned on in response to an emission control signal of the second sub emission control line SEL2.

The fifth transistor T5 is connected between the anode AE of the light emitting element LD and an initialization voltage node VINTN. The initialization voltage node VINTN is configured to transmit an initialization voltage. In one or more embodiments, the initialization voltage may be provided by the voltage generator 140 of FIG. 1. In one or more embodiments, the initialization voltage may be provided by an external device of the display device 100. A gate of the fifth transistor T5 may be connected to the third sub gate line SGL3, and thus the fifth transistor T5 may be turned on in response to a gate signal of the third sub gate line SGL3.

The sixth transistor T6 is connected between the first power voltage node VDDN and the first transistor T1. A gate of the sixth transistor T6 may be connected to the first sub emission control line SEL1, and thus the sixth transistor T6 may be turned on in response to an emission control signal of the first sub emission control line SEL1.

The first capacitor C1 is connected between the second transistor T2 and the second node N2. The second capacitor C2 is connected between the first power voltage node VDDN and the second node N2.

As described above, the sub-pixel circuit SPC may include the first to sixth transistors T1 to T6, and the first and second capacitors C1 and C2. However, embodiments are not limited thereto. The sub-pixel circuit SPC may be implemented as one of one or more suitable types (kinds) of circuits including a plurality of transistors and one or more capacitors. For example, the sub-pixel circuit SPC may include two transistors and one capacitor. According to one or more embodiments of the sub-pixel circuit SPC, the number of sub gate lines included in the i-th gate line GLi′ and the number of sub emission control lines included in the i-th emission control line ELi′ may suitably vary.

The first to sixth transistors T1 to T6 may be P-type or kind transistors. Each of the first to sixth transistors T1 to T6 may be a metal oxide silicon field effect transistor (MOSFET). However, embodiments are not limited thereto. For example, at least one of (e.g., selected from among) the first to sixth transistors T1 to T6 may be replaced with an N-type or kind transistor.

In one or more embodiments, the first to sixth transistors T1 to T6 may include an amorphous silicon semiconductor, a monocrystalline silicon semiconductor, a polycrystalline silicon semiconductor, an oxide semiconductor, and/or the like.

The light emitting element LD may include the anode AE, the cathode CE, and a light emitting layer. The light emitting layer may be arranged between the anode AE and the cathode CE. After the data signal transmitted through the j-th data line DLj is reflected in the voltage of the second node N2, if (e.g., when) the emission control signals of the first and second sub emission control lines SEL1 and SEL2 are enabled to a low level, the fourth and sixth transistors T4 and T6 may be turned on. In addition, the first transistor T1 may be turned on according to the voltage of the second node N2, and thus allowing a current to flow from the first power voltage node VDDN to the second power voltage node VSSN. The light emitting element LD may then emit light according to an amount of the flowing current.

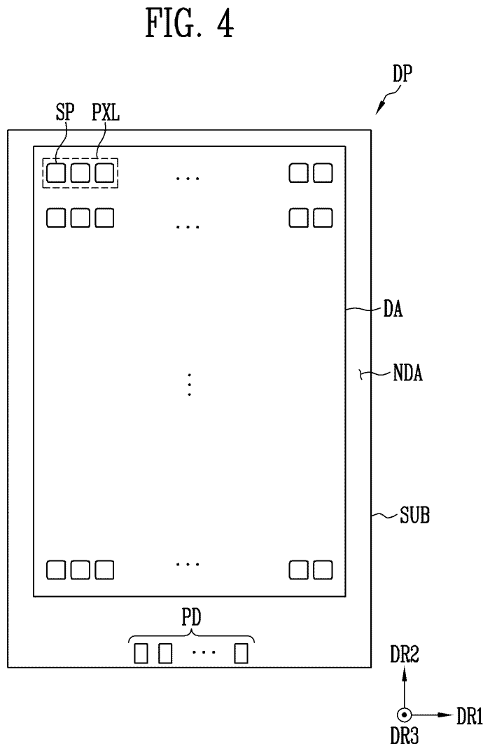

FIG. 4 is a plan view of a display panel according to one or more embodiments.

Referring to FIG. 4, according to one or more embodiments, DP of the display panel 110 of FIG. 1 may include the display area DA and a non-display area NDA. The display panel DP displays an image through the display area DA. The non-display area NDA is arranged around the display area DA.

The display panel DP may include a substrate SUB, the sub-pixels SP, and pads PD.

When the display panel DP is used as a display screen of a head mounted display (HMD), a virtual reality (VR) device, a mixed reality (MR) device, an augmented reality (AR) device, and/or the like, the display panel 110 may be positioned very close to user's eyes. In this case, sub-pixels SP of a relatively higher integration degree is desired or required. In order to increase an integration degree of the sub-pixels SP, a silicon substrate may be provided as the substrate SUB. The sub-pixels SP and/or the display panel DP may be formed on the substrate SUB, which is the silicon substrate. The display device 100 (refer to FIG. 1) including the display panel DP formed on the substrate SUB, which is the silicon substrate, may be referred to as an OLED on silicon (OLEDoS) display device.

The sub-pixels SP is arranged in the display area DA on the substrate SUB. The sub-pixels SP may be arranged in a matrix shape along a first direction DR1 and a second direction DR2 crossing the first direction DR1. However, embodiments are not limited thereto. For example, the sub-pixels SP may be arranged in a zigzag shape along the first direction DR1 and the second direction DR2. For example, the sub-pixels SP may be arranged in a PENTILE™ shape. The first direction DR1 may be a row direction, and the second direction DR2 may be a column direction.

Two or more sub-pixels among (e.g., selected from among) the plurality of sub-pixels SP may configure (e.g., form) one pixel PXL.

A component for controlling the sub-pixels SP may be arranged in the non-display area NDA on the substrate SUB. For example, lines connected to the sub-pixels SP, such as the first to m-th gate lines GL1 to GLm and the first to n-th data lines DL1 to DLn of FIG. 1, may be arranged in the non-display area NDA.

At least one from among (e.g., selected from among) the gate driver 120, the data driver 130, the voltage generator 140, the controller 150, and the temperature sensor 160 of FIG. 1 may be integrated in the non-display area NDA of the display panel DP. In one or more embodiments, the gate driver 120 of FIG. 1 may be mounted on the display panel DP and may be arranged in the non-display area NDA. In one or more embodiments, the gate driver 120 may be implemented as an integrated circuit separated from the display panel DP. In one or more embodiments, the temperature sensor 160 may be arranged in the non-display area NDA to sense a temperature of the display panel DP.

The pads PD are arranged in the non-display area NDA on the substrate SUB. The pads PD may be electrically connected to the sub-pixels SP through lines. For example, the pads PD may be connected to the sub-pixels SP through the first to n-th data lines DL1 to DLn.

The pads PD may interface (e.g., connect) the display panel DP to other components of the display device 100 (refer to FIG. 1). In one or more embodiments, voltages and signals (e.g., necessary) for an operation of components included in the display panel DP may be provided from the driver integrated circuit DIC of FIG. 1 through the pads PD. For example, the first to n-th data lines DL1 to DLn may be connected to the driver integrated circuit DIC through the pads PD. For example, the first and second power voltages VDD and VSS may be received from the driver integrated circuit DIC through the pads PD. For example, if (e.g., when) the gate driver 120 is mounted on the display panel DP, the gate control signal GCS may be transmitted from the driver integrated circuit DIC to the gate driver 120 through the pads PD.

In one or more embodiments, a circuit board may be electrically connected to the pads PD using a conductive adhesive member such as an anisotropic conductive film. In one or more embodiments, the circuit board may be a flexible circuit board (FPCB) or a flexible film having a flexible material. The driver integrated circuit DIC may be mounted on the circuit board to be electrically connected to the pads PD.

In one or more embodiments, the display area DA may have one or more suitable shapes. The display area DA may have a closed loop shape including straight and/or curved sides. For example, the display area DA may have shapes such as a polygon, a circle, a semicircle, and/or an ellipse.

In one or more embodiments, the display panel DP may have a flat display surface. In one or more embodiments, the display panel DP may have a display surface that is at least partially round. In one or more embodiments, the display panel DP may be bendable, foldable, and/or rollable. In these cases, the display panel DP and/or the substrate SUB may include materials having a flexible property (e.g., suitable flexibility).

FIG. 5 is a diagram of a pixel according to one or more embodiments.

Referring to FIG. 5, the pixel PXL may include first to third sub-pixels SP1 to SP3. Each of the first to third sub-pixels SP1 to SP3 may generate light of one of one or more suitable colors such as red, green, blue, cyan, magenta, or yellow. Hereinafter, for convenience of description, it is assumed that the first sub-pixel SP1 is configured to generate light of a red color, the second sub-pixel SP2 is configured to generate light of a green color, and the third sub-pixel SP3 is configured to generate light of a blue color. However, embodiments are not limited thereto. For example, the pixel PXL may further include a sub-pixel that generates light of a white color in addition to the first to third sub-pixels SP1 to SP3.

The substrate SUB may include a silicon wafer substrate formed using a semiconductor process. The substrate SUB may include a semiconductor material suitable for forming circuit elements. For example, the semiconductor material may include silicon, germanium, and/or silicon-germanium. The substrate SUB may be provided from a bulk wafer, an epitaxial layer, a silicon on insulator (SOI) layer, a semiconductor on insulator (SeOI) layer, and/or the like. However, embodiments are not limited thereto. For example, the substrate SUB may include a glass substrate or a polyimide (PI) substrate.

A pixel circuit layer PCL may be arranged on the substrate SUB. The substrate SUB and/or the pixel circuit layer PCL may include insulating layers and conductive patterns arranged between the insulating layers. The conductive patterns of the pixel circuit layer PCL may function as at least a portion of circuit elements, lines, and/or the like. The conductive patterns may include copper, but embodiments are not limited thereto.

The circuit elements may include the sub-pixel circuit SPC (refer to FIG. 2) for each of the first to third sub-pixels SP1 to SP3. The sub-pixel circuit SPC may include transistors and one or more capacitors. Each transistor may include a semiconductor portion including a source area, a drain area, and a channel area, and a gate electrode overlapping the semiconductor portion. In one or more embodiments, if (e.g., when) the substrate SUB is provided as a silicon substrate, the semiconductor portion may be included in the substrate SUB, and the gate electrode may be included in the pixel circuit layer PCL as a conductive pattern of the pixel circuit layer PCL. In one or more embodiments, if (e.g., when) the substrate SUB is provided as a glass substrate or a PI substrate, the semiconductor portion and the gate electrode may be included in the pixel circuit layer PCL.

The lines of the pixel circuit layer PCL may include signal lines connected to each of the first to third sub-pixels SP1 to SP3, for example, a gate line, an emission control line, a data line, and/or the like. The lines may further include a line connected to the first power voltage node VDDN of FIG. 2. In addition, the lines may further include a line connected to the second power voltage node VSSN of FIG. 2.

First to third anodes AE1 to AE3 may be arranged on the pixel circuit layer PCL. The first to third anodes AE1 to AE3 may be spaced and/or apart (e.g., spaced apart or separated) from each other and may be included in the first to third sub-pixels SP1 to SP3, respectively. The first anode AE1 may receive an electrical signal for driving the first sub-pixel SP1 from the pixel circuit layer PCL. The second anode AE2 may receive an electrical signal for driving the second sub-pixel SP2 from the pixel circuit layer PCL. The third anode AE3 may receive an electrical signal for driving the third sub-pixel SP3 from the pixel circuit layer PCL.

The first to third anodes AE1 to AE3 may include at least one selected from among indium tin oxide (ITO), indium zinc oxide (IZO), zinc oxide (ZnOx), indium gallium zinc oxide (IGZO), indium tin zinc oxide (ITZO), titanium (Ti), titanium nitride (TiN), tantalum nitride (TaN), silver (Ag), magnesium (Mg), aluminum (Al), and nickel (Ni). For example, the first to third anodes AE1 to AE3 may be configured as having a multiple layer structure of Ag/ITO or a multiple layer structure of Al/TiN. However, embodiments are not limited thereto.

A hole injection layer HIL may be arranged on the first to third anodes AE1 to AE3. For example, the hole injection layer HIL may be directly arranged on the first to third anodes AE1 to AE3 and contact the first to third anodes AE1 to AE3.

In one or more embodiments, the hole injection layer HIL may be configured as a single layer. For example, the hole injection layer HIL may be provided (e.g., entirely) over all of the first to third sub-pixels SP1 to SP3 in a single layer form. That is, the hole injection layer HIL is a continuous layer over all of the first to third sub-pixels SP1 to SP3.

In one or more embodiments, the hole injection layer HIL may include a triazine compound. For example, the hole injection layer HIL may include at least one of (e.g., selected from among) the first to eighth triazine compounds TA1 to TA8.

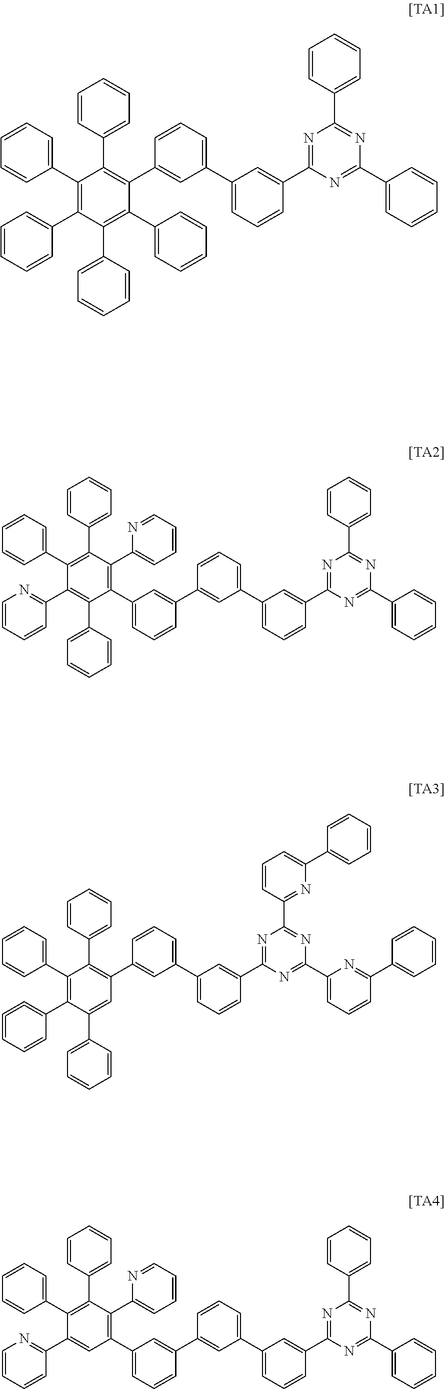 [SMILES: c1ccc(-c2nc(-c3ccccc3)nc(-c3cccc(-c4cccc(-c5c(-c6ccccc6)c(-c6ccccc6)c(-c6ccccc6)c(-c6ccccc6)c5-c5ccccc5)c4)c3)n2)cc1 ; c1ccc(-c2nc(-c3ccccc3)nc(-c3cccc(-c4cccc(-c5cccc(-c6c(-c7ccccc7)c(-c7ccccn7)c(-c7ccccc7)c(-c7ccccc7)c6-c6ccccn6)c5)c4)c3)n2)cc1 ; C1=C=C(c2c(-c3ccccc3)cc(-c3cccc(-c4cccc(-c5nc(-c6cccc(-c7ccccc7)n6)nc(-c6cccc(-c7ccccc7)n6)n5)c4)c3)c(-c3ccccc3)c2-c2ccccc2)C=CC=1 ; c1ccc(-c2nc(-c3ccccc3)nc(-c3cccc(-c4cccc(-c5cccc(-c6cc(-c7ccccn7)c(-c7ccccc7)c(-c7ccccc7)c6-c6ccccn6)c5)c4)c3)n2)cc1]

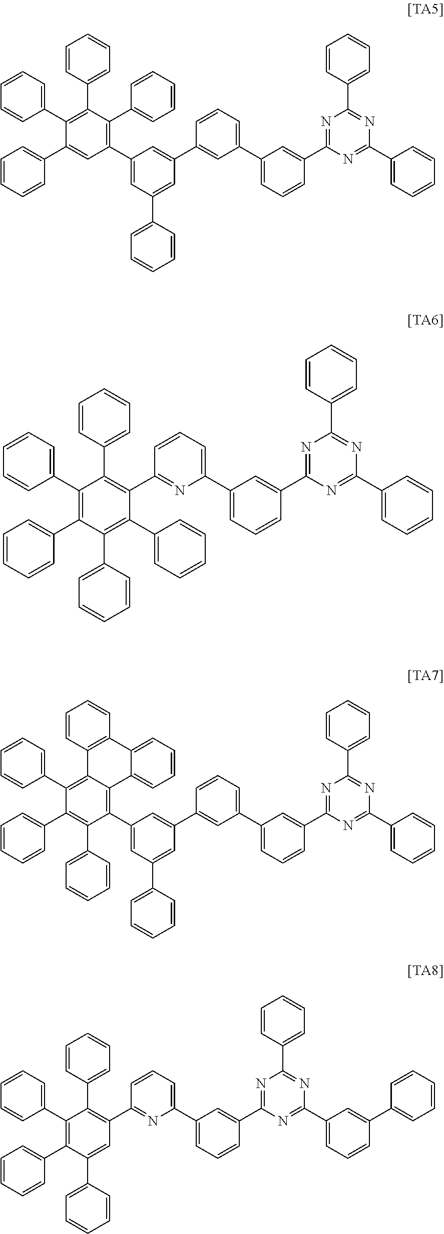

In one or more embodiments, the hole injection layer HIL may include a pyrimidine compound. For example, the hole injection layer HIL may include at least one of (e.g., selected from among) the first to eighth pyrimidine compounds P1 to P8.

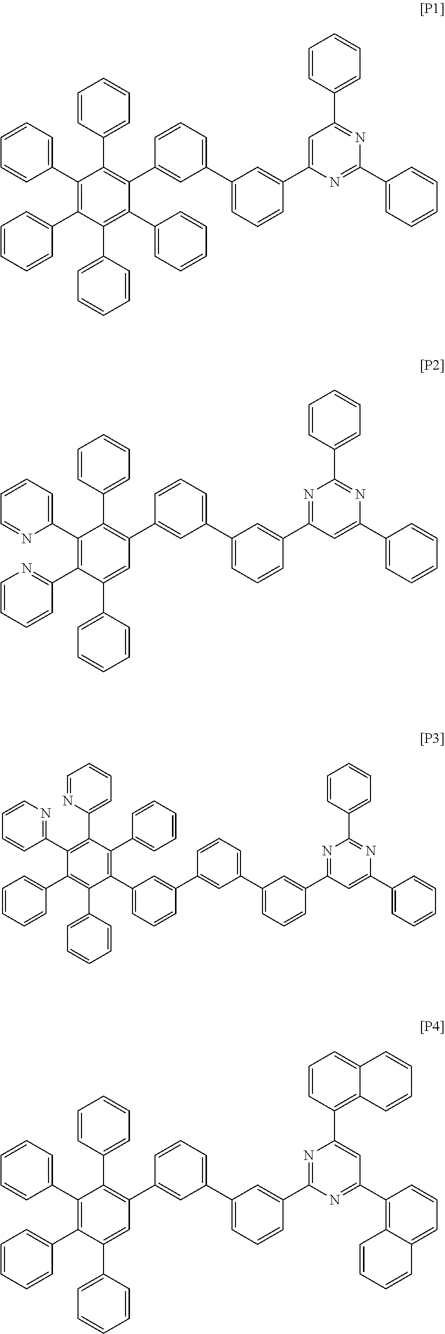 [SMILES: c1ccc(-c2cc(-c3cccc(-c4cccc(-c5c(-c6ccccc6)c(-c6ccccc6)c(-c6ccccc6)c(-c6ccccc6)c5-c5ccccc5)c4)c3)nc(-c3ccccc3)n2)cc1 ; c1ccc(-c2cc(-c3cccc(-c4cccc(-c5cc(-c6ccccc6)c(-c6ccccn6)c(-c6ccccn6)c5-c5ccccc5)c4)c3)nc(-c3ccccc3)n2)cc1 ; c1ccc(-c2cc(-c3cccc(-c4cccc(-c5cccc(-c6c(-c7ccccc7)c(-c7ccccc7)c(-c7ccccn7)c(-c7ccccn7)c6-c6ccccc6)c5)c4)c3)nc(-c3ccccc3)n2)cc1 ; c1ccc(-c2cc(-c3cccc(-c4cccc(-c5nc(-c6cccc7ccccc67)cc(-c6cccc7ccccc67)n5)c4)c3)c(-c3ccccc3)c(-c3ccccc3)c2-c2ccccc2)cc1]

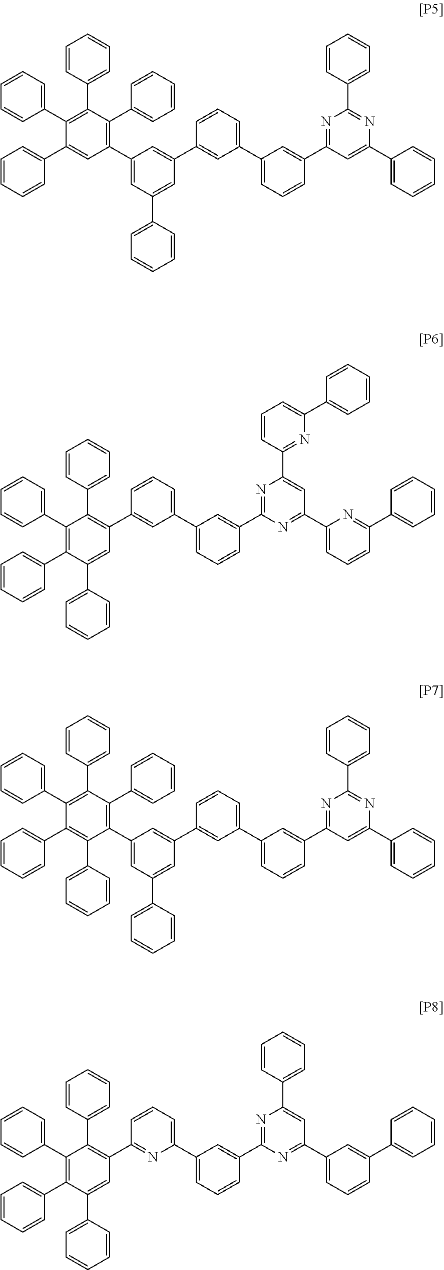

Hereinafter, for convenience of description, it is assumed that the hole injection layer HIL includes a triazine compound or a pyrimidine compound.

In one or more embodiments, the highest occupied molecular orbital (HOMO) energy level of the hole injection layer HIL may be −6.3 to −5 eV. When the HOMO energy level of the hole injection layer HIL satisfies the above-described range, holes may be stably injected from the first to third anodes AE1 to AE3 into the hole injection layer HIL. For example, stability of a hole injection characteristic may be increased.

In one or more embodiments, a dipole moment of the hole injection layer HIL may be 1 to 6 D (Debye). When the dipole moment of the hole injection layer HIL satisfies the above-described range, the holes may be rapidly injected from the first to third anodes AE1 to AE3 into the hole injection layer HIL. For example, an efficiency of the hole injection characteristic may be increased.

In one or more embodiments, a thickness of the hole injection layer HIL may be 0.5 to 50 angstroms (Å). The thickness may be a length measured in a third direction DR3. When the thickness of the hole injection layer HIL satisfies the above-described range, the above-described hole injection characteristics may be secured without increasing a driving voltage.

A hole transport layer HTL may be arranged on the hole injection layer HIL. The hole transport layer HTL may be provided (e.g., entirely) over all of the first to third sub-pixels SP1 to SP3 (e.g., as a continuous layer). However, embodiments are not limited thereto. For example, the hole transport layer HTL may be provided in a spaced and/or apart (e.g., spaced apart or separated) form and included in each of the first to third sub-pixels SP1 to SP3. That is, the hole transport layer (HTL) may be provided in a patterned form and included in each of the first to third sub-pixels (SP1 to SP3).

The hole transport layer HTL may include at least one selected from among a carbazole-based derivative such as N-phenylcarbazole and/or polyvinylcarbazole, a fluorene-based derivative, a triphenylamine derivative such as TPD (N,N′-bis(3-methylphenyl)-N,N′-diphenyl-[1,1-biphenyl]-4,4′-diamine) and/or TCTA (4,4′,4″-tris(N-carbazolyl)triphenylamine), NPB (N,N′-di(naphthalene-1-yl)-N,N′-diphenyl-benzidine), TAPC (4,4′-Cyclohexylidene bis[N,N-bis(4-methylphenyl)benzenamine]), HMTPD (4,4′-Bis[N,N′-(3-tolyl)amino]-3,3′-dimethylbiphenyl), mCP (1,3-Bis(N-carbazolyl)benzene), and CzSi (9-(4-tert-Butylphenyl)-3,6-bis(triphenylsilyl)-9H-carbazole). However, embodiments are not limited thereto.

First to third auxiliary layers IL1 to IL3 may be arranged on the hole transport layer HTL. The first to third auxiliary layers IL1 to IL3 may be included in the first to third sub-pixels SP1 to SP3, respectively.

The first auxiliary layer IL1 may be configured as multiple layers. For example, the first auxiliary layer IL1 may include a resonance auxiliary layer arranged on the hole transport layer HTL and a light emitting auxiliary layer arranged on the resonance auxiliary layer. The resonance auxiliary layer of the first auxiliary layer IL1 may serve to control a resonance distance of the light of the red color emitted from a first light emitting layer EML1. The light emitting auxiliary layer of the first auxiliary layer IL1 may serve to increase an emission efficiency of the first light emitting layer EML1 by adjusting a hole-charge balance. However, embodiments are not limited thereto. For example, the first auxiliary layer IL1 may be configured as a single layer including a light emitting auxiliary layer.

The second auxiliary layer IL2 may be configured as multiple layers. For example, the second auxiliary layer IL2 may include a resonance auxiliary layer arranged on the hole transport layer HTL and a light emitting auxiliary layer arranged on the resonance auxiliary layer. The resonance auxiliary layer of the second auxiliary layer IL2 may serve to control a resonance distance of the light of the green color emitted from a second light emitting layer EML2. The light emitting auxiliary layer of the second auxiliary layer IL2 may serve to increase an emission efficiency of the second light emitting layer EML2 by adjusting a hole charge balance. However, embodiments are not limited thereto. For example, the second auxiliary layer IL2 may be configured as a single layer including a light emitting auxiliary layer.

The third auxiliary layer IL3 may be configured as a single layer. For example, the third auxiliary layer IL3 may include a light emitting auxiliary layer arranged on the hole transport layer HTL. Different from the first and second auxiliary layers IL1 and IL2, the third auxiliary layer IL3 may not include (e.g., may exclude) a resonance auxiliary layer. The light emitting auxiliary layer of the third auxiliary layer IL3 may serve to increase an emission efficiency of the third light emitting layer EML3 by adjusting a hole charge balance.

The first to third light emitting layers EML1 to EML3 may be respectively arranged on the first to third auxiliary layers IL1 to IL3. Holes transmitted from the first to third anodes AE1 to AE3 and electrons transmitted from the cathode CE may recombine in the respective first to third light emitting layers EML1 to EML3 to form excitons. When the excitons transition from an excited state to a ground state, light may be generated. The first light emitting layer EML1 may generate the light of the red color. The second light emitting layer EML2 may generate the light of the green color. The third light emitting layer EML3 may generate the light of the blue color. Each of the first to third light emitting layers EML1 to EML3 may include an organic light emitting material that generates light of a corresponding color. However, embodiments are not limited thereto. For example, each of the first to third light emitting layers EML1 to EML3 may include an inorganic light emitting material, a quantum dot, and/or the like.

A buffer layer BFL may be arranged on the first to third light emitting layers EML1 to EML3. The buffer layer BFL may be provided (e.g., entirely) over all of the first to third sub-pixels SP1 to SP3 (e.g., as a continuous layer). The buffer layer BFL may serve to control the injection of electrons from the cathode CE into the first to third light emitting layers EML1 to EML3. Accordingly, the holes and the electrons may be uniformly (e.g., substantially uniformly) injected into the first to third light emitting layers EML1 to EML3.

The electron transport layer ETL may be arranged on the buffer layer BFL. The electron transport layer ETL may be provided (e.g., entirely) over all of the first to third sub-pixels SP1 to SP3 (e.g., as a continuous layer). The electron transport layer ETL may include at least one of Alq₃ (Tris(8-hydroxyquinolinato)aluminum), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-Dimethyl-4,7-diphenyl-1,10-phenanthroline), Bphen (4,7-Diphenyl-1,10-phenanthroline), TAZ (3-(4-Biphenylyl)-4-phenyl-5-tert-butylphenyl-1,2,4-triazole), NTAZ (4-(Naphthalen-1-yl)-3,5-diphenyl-4H-1,2,4-triazole), tBu-PBD (2-(4-Biphenylyl)-5-(4-tert-butylphenyl)-1,3,4-oxadiazole), BAlq (Bis(2-methyl-8-quinolinolato-N1,O8)-(1,1′-Biphenyl-4-olato)aluminum), Bebq₂ (beryllium bis(benzoquinolin-10-olate), ADN (9,10-di(naphthalen-2-yl)anthracene), and TSPO1 (diphenyl(4-(triphenylsilyl)phenyl)phosphine oxide). However, embodiments are not limited thereto.

An electron injection layer EIL may be arranged on the electron transport layer ETL. The electron injection layer EIL may be provided (e.g., entirely) over all of the first to third sub-pixels SP1 to SP3 (e.g., as a continuous layer). The electron injection layer EIL may include at least one selected from among a halogenated metal such as LiF, NaCl, CsF, RbCl, and/or Rbl, a lanthanide metal such as Yb, a metal oxide such as Li₂O and/or BaO, and lithium quinolate (LiQ). However, embodiments are not limited thereto.

The cathode CE may be arranged on the electron injection layer EIL. The cathode CE may be provided (e.g., entirely) over all of the first to third sub-pixels SP1 to SP3 (e.g., as a continuous layer). The cathode CE may be a thin metal layer having a thickness sufficient to transmit light emitted from the first to third light emitting layers EML1 to EML3. The cathode CE may be formed of a transparent conductive material or a metal material to have a relatively thin thickness. For example, the cathode CE may include at least one of one or more suitable transparent conductive materials including indium tin oxide, indium zinc oxide, indium tin zinc oxide, aluminum zinc oxide, gallium zinc oxide, zinc tin oxide, or gallium tin oxide. For example, the cathode CE may include at least one of silver (Ag), magnesium (Mg), and/or a (e.g., any suitable) mixture thereof. However, embodiments are not limited thereto.

The first to third sub-pixels SP1 to SP3 may include first to third light emitting elements LD1 to LD3, respectively. The first light emitting element LD1 may include the first anode AE1, a portion of the hole injection layer HIL overlapping therewith, a portion of the hole transport layer HTL overlapping therewith, the first auxiliary layer IL1, the first light emitting layer EML1, a portion of the buffer layer BFL overlapping therewith, a portion of the electron transport layer ETL overlapping therewith, a portion of the electron injection layer EIL overlapping therewith, and a portion of the cathode CE overlapping therewith. The second light emitting element LD2 may include the second anode AE2, a portion of the hole injection layer HIL overlapping therewith, a portion of the hole transport layer HTL overlapping therewith, the second auxiliary layer IL2, the second light emitting layer EML2, a portion of the buffer layer BFL overlapping therewith, a portion of the electron transport layer ETL overlapping therewith, a portion of the electron injection layer EIL overlapping therewith, and the cathode CE overlapping therewith. The third light emitting element LD3 may include the third anode AE3, a portion of the hole injection layer HIL overlapping therewith, a portion of the hole transport layer HTL overlapping therewith, the third auxiliary layer IL3, the third light emitting layer EML3, a portion of the buffer layer BFL overlapping therewith, a portion of the electron transport layer ETL overlapping therewith, a portion of the electron injection layer EIL overlapping therewith, and the cathode CE overlapping therewith.

The capping layer CPL may be arranged on the cathode CE. The capping layer CPL may be provided (e.g., entirely) over all of the first to third sub-pixels SP1 to SP3 (e.g., as a continuous layer). The capping layer CPL may serve to prevent or reduce a foreign substance such as oxygen and moisture from permeating inside.

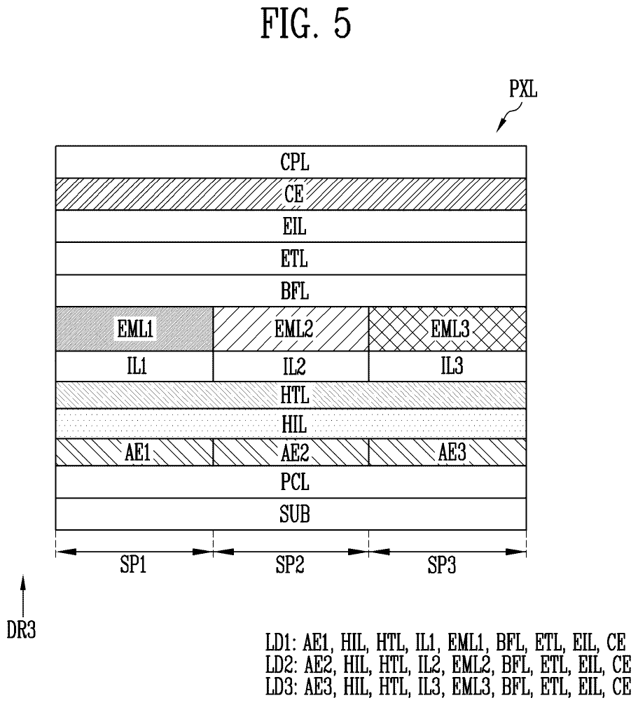

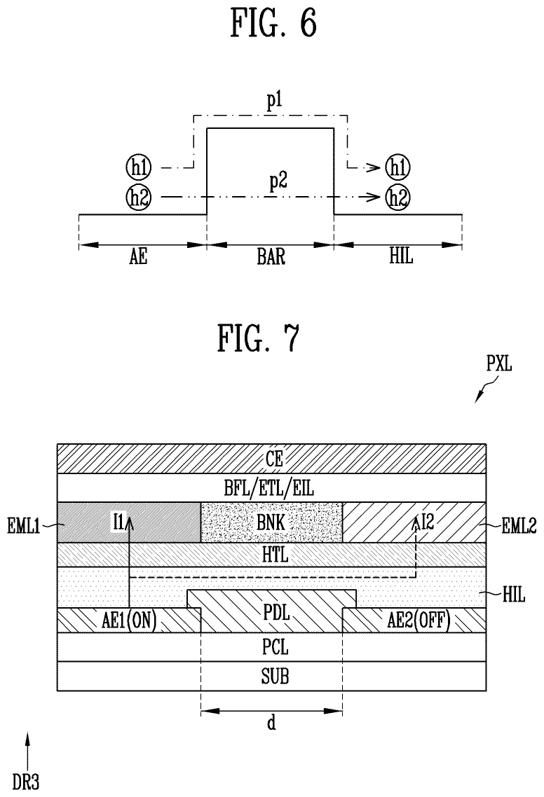

FIG. 6 is a diagram of a characteristic of a hole injection layer according to one or more embodiments. In FIG. 6, the anode AE may be one of the first to third anodes AE1 to AE3 shown in FIG. 5.

Referring to FIG. 6, the holes provided from the anode AE may be injected into the hole injection layer HIL through a barrier (e.g., energy barrier) BAR. Hereinafter, for convenience of description, it is assumed that the holes include a first hole h1 and a second hole h2.

The first hole h1 may be injected into the hole injection layer HIL through a first path p1. For example, the first holes h1 may cross over the barrier BAR and may be injected into the hole injection layer HIL. The first hole h1 may have an energy higher than that of the barrier BAR by heat (e.g., when heated) and may be injected into the hole injection layer HIL beyond the barrier BAR. For example, the first holes h1 may be injected into the hole injection layer HIL by thermionic emission. In one or more embodiments, the first holes h1 may form a charge transfer complex (CT complex) and may be injected into the hole injection layer HIL beyond the barrier BAR. When the holes provided from the anode AE move through the first path p1, which requires the energy (e.g., of the holes being) higher than that of the barrier BAR, such as the first hole h1, a hole injection characteristic may be decreased.

The second hole h2 may be injected into the hole injection layer HIL through a second path p2. For example, the second hole h2 may have an energy lower than that of the barrier BAR, but may pass through the barrier BAR and may be injected into the hole injection layer HIL. For example, the second hole h2 may be injected into the hole injection layer HIL by quantum tunneling.

In one or more embodiments, the holes provided from the anode AE may be injected into the hole injection layer HIL through the second path p2 as well as the first path p1. That is, the first hole h1 may be injected into the hole injection layer HIL through the first path p1. For example, the first holes h1 may “cross over” the barrier BAR and be injected into the hole injection layer HIL. Conversely, the second hole h2 may be injected into the hole injection layer HIL through the second path p2. For example, the second hole h2 may have an energy lower than that of the barrier BAR, but it can still “pass through” the barrier BAR and be injected into the hole injection layer HIL by quantum tunneling. Therefore, the hole injection characteristic may be increased (or improved) because the holes provided from the anode AE may be injected into the HIL through the second path p2 as well as the first path p1.

### Experimental Example 1

A driving voltage, an emission efficiency, and a lifespan of the first light emitting elements LD1 (refer to FIG. 5) according to Comparative examples 1-BDto 1-3 and Examples 1-2 to 1-9 are measured and shown in Table 1. Hereinafter, NDP-9 is 2-(7-Dicyanomethylene-1,3,4,5,6,8,9,10-octafluoro-7H-pyren-2-ylidene)-malononitrile and is used as the hole injection layer HIL. Hereinafter, HTM081 is a compound manufactured by Merck and is used as the hole injection layer HIL and/or the hole transport layer HTL.

TABLE 1

| | | | | Driving | Emission | |
|---|---|---|---|---|---|---|
| | AE1 | HIL | HTL | voltage | efficiency | Lifespan |
| Comparative | ITO | NPB + | NPB | 100% | 100% | 100% |
| example 1-1 | | NDP-9 | | | | |
| Comparative | TiN | NPB + | NPB | 112% | 97% | 92% |
| example 1-2 | | NDP-9 | | | | |
| Comparative | TiN | HTM081 + | HTM081 | 113% | 95% | 87% |
| example 1-3 | | NDP-9 | | | | |
| Example 1-1 | ITO | TA1 | NPB | 100% | 103% | 125% |
| Example 1-2 | ITO | P1 | NPB | 100% | 104% | 130% |
| Example 1-3 | ITO | P7 | NPB | 100% | 105% | 133% |
| Example 1-4 | TiN | TA1 | NPB | 92% | 107% | 123% |
| Example 1-5 | TiN | P1 | NPB | 90% | 109% | 142% |
| Example 1-6 | TiN | P7 | NPB | 87% | 109% | 152% |
| Example 1-7 | TiN | TA1 | HTM081 | 92% | 108% | 131% |
| Example 1-8 | TiN | P1 | HTM081 | 90% | 107% | 148% |
| Example 1-9 | TiN | P7 | HTM081 | 87% | 109% | 165% |

Referring to Table 1, it may be seen that the emission efficiency and the lifespan of each of Examples 1-1 to 1-9 including the hole injection layer HIL configured of (e.g., composed of, including or consisting of) the triazine compound or the pyrimidine compound are increased without increasing the driving voltage compared to Comparative examples 1-1 to 1-3.

### Experimental Example 2

A driving voltage, an emission efficiency, and a lifespan of the second light emitting elements LD2 (refer to FIG. 5) according to Comparative examples 2-1 to 2-3 and Examples 2-1 to 2-9 are measured and shown in Table 2.

TABLE 2

| | | | | Driving | Emission | |
|---|---|---|---|---|---|---|
| | AE2 | HIL | HTL | voltage | efficiency | Lifespan |
| Comparative | ITO | NPB + | NPB | 100% | 100% | 100% |
| example 2-1 | | NDP-9 | | | | |
| Comparative | TiN | NPB + | NPB | 115% | 93% | 84% |
| example 2-2 | | NDP-9 | | | | |
| Comparative | TiN | HTM081 + | HTM081 | 120% | 91% | 83% |
| example 2-3 | | NDP-9 | | | | |
| Example 2-1 | ITO | TA1 | NPB | 100% | 101% | 115% |
| Example 2-2 | ITO | P1 | NPB | 100% | 104% | 120% |
| Example 2-3 | ITO | P7 | NPB | 100% | 102% | 125% |
| Example 2-4 | TiN | TA1 | NPB | 94% | 110% | 125% |
| Example 2-5 | TiN | P1 | NPB | 92% | 112% | 130% |
| Example 2-6 | TiN | P7 | NPB | 90% | 110% | 145% |
| Example 2-7 | TiN | TA1 | HTM081 | 92% | 107% | 136% |
| Example 2-8 | TiN | P1 | HTM081 | 91% | 107% | 150% |
| Example 2-9 | TiN | P7 | HTM081 | 89% | 111% | 165% |

Referring to Table 2, it may be seen that the emission efficiency and the lifespan of each of Examples 2-1 to 2-9 including the hole injection layer HIL configured of the triazine compound or the pyrimidine compound are increased without increasing the driving voltage compared to Comparative examples 2-1 to 2-3.

### Experimental Example 3

A driving voltage, an emission efficiency, and a lifespan of the third light emitting elements LD3 (refer to FIG. 5) according to Comparative examples 3-1 to 3-3 and Examples 3-1 to 3-9 are measured and shown in Table 3.

TABLE 3

| | | | | Driving | Emission | |
|---|---|---|---|---|---|---|
| | AE3 | HIL | HTL | voltage | efficiency | Lifespan |
| Comparative | ITO | NPB + | NPB | 100% | 100% | 100% |
| example 3-1 | | NDP-9 | | | | |
| Comparative | TiN | NPB + | NPB | 110% | 95% | 85% |
| example 3-2 | | NDP-9 | | | | |
| Comparative | TiN | HTM081 + | HTM081 | 115% | 92% | 80% |
| example 3-3 | | NDP-9 | | | | |
| Example 3-1 | ITO | TA1 | NPB | 100% | 102% | 120% |
| Example 3-2 | ITO | P1 | NPB | 100% | 105% | 125% |
| Example 3-3 | ITO | P7 | NPB | 100% | 106% | 135% |
| Example 3-4 | TiN | TA1 | NPB | 95% | 108% | 130% |
| Example 3-5 | TiN | P1 | NPB | 93% | 110% | 145% |
| Example 3-6 | TiN | P7 | NPB | 90% | 109% | 160% |
| Example 3-7 | TiN | TA1 | HTM081 | 93% | 107% | 135% |
| Example 3-8 | TiN | P1 | HTM081 | 92% | 106% | 155% |
| Example 3-9 | TiN | P7 | HTM081 | 89% | 110% | 180% |

Referring to Table 3, it may be seen that the emission efficiency and the lifespan of each of Examples 3-1 to 3-9 including the hole injection layer HIL configured of the triazine compound or the pyrimidine compound are increased without increasing the driving voltage compared to Comparative examples 3-1 to 3-3.

### Experimental Example 4

FIG. 7 is a cross-sectional view of a pixel according to one or more embodiments. In FIG. 7, a pixel PXL including first and second anodes AE1 and AE2 adjacent to each other is shown as an example. In addition, a bank BNK arranged between the first emitting layer EML1 and the second emitting layer EML2 to prevent or reduce color mixing is shown as an example.

Referring to FIG. 7, if (e.g., when) a driving signal is supplied to the first anode AE1, holes provided from the first anode AE1 may be injected into the first emitting layer EML1, and the light of the red color corresponding to the driving current I1 may be generated. Because the driving signal is not supplied to the second anode AE2, the light of the green color is desired or required not to be generated in the second light emitting layer EML2. However, as a resistance of the first emitting layer EML1 increases and the holes injected from the first anode AE1 are injected into the second emitting layer EML2 through the hole injection layer HIL, the light of the green color corresponding to a leakage current I2 may be generated. In this case, the light of the red color and the light of the green color may be mixed, color reproducibility may be deteriorated, and display performance at a low grayscale may be deteriorated. This phenomenon may be increased (e.g., become worse) as a distance d between the first and second anodes AE1 and AE2 or adjacent anodes is decreased and a resistance of the hole injection layer HIL is decreased because a side leakage is increased. In other words, the likelihood of this undesirable phenomenon intensifying, or worsening, is heightened when the separation distanced between the first and second anodes AE1 and AE2, or adjacent anodes, is reduced. This is further exacerbated by a decrease in the resistance of the hole injection layer HIL, which leads to an increase in the side leakage.

The leakage current I2 of Comparative examples 4-1 to 4-3 and Examples 4-1 to 4-9 according to the distance (i.e., chosen from first to fourth distances d1 to d4) between the first and second anodes AE1 and AE2 adjacent to each other is measured and shown in Table 4.

TABLE 4

| | AE1, | | | Leakage current (I2) (mA) | | | |
|---|---|---|---|---|---|---|---|
| | AE2 | HIL | HTL | d1(100 um) | d2(10 um) | d3(5 um) | d4(2 um) |
| Comparative | ITO | NPB + | NPB | 6.5 × 10⁻⁷ | 5.4 × 10⁻³ | 3.8 × 10⁻² | 2.1 × 10 |
| example 4-1 | | NDP-9 | | | | | |
| Comparative | TIN | NPB + | NPB | 7.2 × 10⁻⁷ | 6.1 × 10⁻³ | 4.8 × 10⁻² | 2.7 × 10 |
| example 4-2 | | NDP-9 | | | | | |
| Comparative | TIN | HTM081 + | HTM081 | 8.5 × 10⁻⁷ | 5.8 × 10⁻³ | 3.8 × 10⁻² | 2.8 × 10 |
| example 4-3 | | NDP-9 | | | | | |
| Example 4-1 | ITO | TA1 | NPB | 5.9 × 10⁻⁹ | 4.5 × 10⁻⁸ | 3.2 × 10⁻⁸ | 1.3 × 10⁻⁸ |
| Example 4-2 | ITO | P1 | NPB | 3.4 × 10⁻⁹ | 8.4 × 10⁻⁸ | 4.3 × 10⁻⁸ | 1.9 × 10⁻⁸ |
| Example 4-3 | ITO | P7 | NPB | 4.5 × 10⁻⁹ | 3.1 × 10⁻⁸ | 2.7 × 10⁻⁸ | 1.4 × 10⁻⁸ |
| Example 4-4 | TiN | TA1 | NPB | 6.2 × 10⁻⁹ | 5.3 × 10⁻⁸ | 3.3 × 10⁻⁸ | 1.4 × 10⁻⁸ |
| Example 4-5 | TiN | P1 | NPB | 3.4 × 10⁻⁹ | 8.4 × 10⁻⁸ | 4.3 × 10⁻⁸ | 1.1 × 10⁻⁸ |
| Example 4-6 | TiN | P7 | NPB | 4.5 × 10⁻⁹ | 3.8 × 10⁻⁸ | 2.7 × 10⁻⁸ | 1.7 × 10⁻⁸ |
| Example 4-7 | TiN | TA1 | HTM081 | 6.9 × 10⁻⁹ | 4.9 × 10⁻⁸ | 3.5 × 10⁻⁸ | 1.8 × 10⁻⁸ |
| Example 4-8 | TiN | P1 | HTM081 | 4.4 × 10⁻⁹ | 7.4 × 10⁻⁸ | 4.7 × 10⁻⁸ | 1.9 × 10⁻⁸ |
| Example 4-9 | TiN | P7 | HTM081 | 5.7 × 10⁻⁹ | 3.8 × 10⁻⁸ | 2.9 × 10⁻⁸ | 1.5 × 10⁻⁸ |

Referring to Table 4, it may be seen that the leakage current I2 of each of Examples 4-1 to 4-9 including the hole injection layer HIL configured of the triazine compound or the pyrimidine compound is less than that of Comparative examples 4-1 to 4-3. For example, it may be seen that the resistance of the hole injection layer HIL is increase and the side leakage of the holes through the hole injection layer HIL is decreased in Examples 4-1 to 4-9.

### Experimental Example 5

A color coordinate and a color change amount according to a grayscale of the red color according to Comparative example 5-1 and Examples 5-1 to 5-3 are measured and shown in Table 5. A color coordinate and a color change amount according to a grayscale of the green color according to comparative example 6-1 and Examples 6-1 to 6-3 are measured and shown in Table 6. A color coordinate and a color change amount according to a grayscale of the blue color according to comparative example 7-1 and Examples 7-1 to 7-3 are measured and shown in Table 7. The color change amount is expressed as x, y change amount of a color coordinate corresponding to 255 grayscales 255G and 5 grayscales 5G for each color.

TABLE 5

| | | | | 255G | | 5G | | 255G − 5G | |
|---|---|---|---|---|---|---|---|---|---|
| | AE1 | HIL | HTL | x | y | x | y | Δx | Δy |
| Comparative | ITO | NPB + | NPB | 0.6826 | 0.323 | 0.674 | 0.3256 | 0.0086 | −0.0026 |
| example 5-1 | | NDP-9 | | | | | | | |
| Example 5-1 | ITO | TA1 | NPB | 0.6832 | 0.3166 | 0.6795 | 0.3195 | 0.0037 | −0.0029 |
| Example 5-2 | ITO | P1 | NPB | 0.6834 | 0.3164 | 0.6805 | 0.3156 | 0.0029 | 0.0008 |
| Example 5-3 | ITO | P7 | NPB | 0.6833 | 0.3165 | 0.6778 | 0.3099 | 0.0055 | 0.0066 |

TABLE 6

| | | | | 255G | | 5G | | 255G − 5G | |
|---|---|---|---|---|---|---|---|---|---|
| | AE2 | HIL | HTL | x | y | x | y | Δx | Δy |
| Comparative | ITO | NPB+ | NPB | 0.2521 | 0.7077 | 0.2116 | 0.7264 | 0.0405 | −0.0187 |
| example 6-1 | | NDP-9 | | | | | | | |
| Example 6-1 | ITO | TA1 | NPB | 0.2519 | 0.7077 | 0.2606 | 0.7002 | −0.0087 | 0.0075 |
| Example 6-2 | ITO | P1 | NPB | 0.2517 | 0.7083 | 0.2758 | 0.6931 | −0.0241 | 0.0152 |
| Example 6-3 | ITO | P7 | NPB | 0.2518 | 0.7081 | 0.230 | 0.7134 | 0.0218 | −0.0053 |

TABLE 7

| | | | | 255G | | 5G | | 255G − 5G | |
|---|---|---|---|---|---|---|---|---|---|
| | AE3 | HIL | HTL | x | y | x | y | Δx | Δy |
| Comparative | ITO | NPB + | NPB | 0.1469 | 0.037 | 0.1746 | 0.0887 | −0.0277 | −0.0517 |
| example 7-1 | | NDP-9 | | | | | | | |
| Example 7-1 | ITO | TA1 | NPB | 0.1469 | 0.0364 | 0.1685 | 0.0642 | −0.0216 | −0.0278 |
| Example 7-2 | ITO | P1 | NPB | 0.1467 | 0.0361 | 0.1585 | 0.0511 | −0.0118 | −0.015 |
| Example 7-3 | ITO | P7 | NPB | 0.1463 | 0.0366 | 0.1561 | 0.05 | −0.0098 | −0.0134 |

Referring to Tables 5 to 7, it may be seen that the color change amount of each of Examples 5-1 to 5-3, 6-1 to 6-3, and 7-1 to 7-3 including the hole injection layer HIL configured of the triazine compound or the pyrimidine compound is less than that of Comparative examples 5-1 to 7-1. For example, in in each of Examples 5-1 to 5-3, 6-1 to 6-3, and 7-1 to 7-3, the side leakage of the holes through the hole injection layer HIL may be decreased, therefore, color reproducibility, display performance at the low grayscale, and/or the like may be increased.

As described above, if (e.g., when) the hole injection layer HIL is configured of the triazine compound or the pyrimidine compound, the HOMO energy level of the hole injection layer HIL is −6.3 ev to −5 eV, and the dipole moment of the hole injection layer HIL is 1 Debye to 6 Debye, the hole injection characteristic may be increased and a hole leakage may be decreased (e.g., reduced).

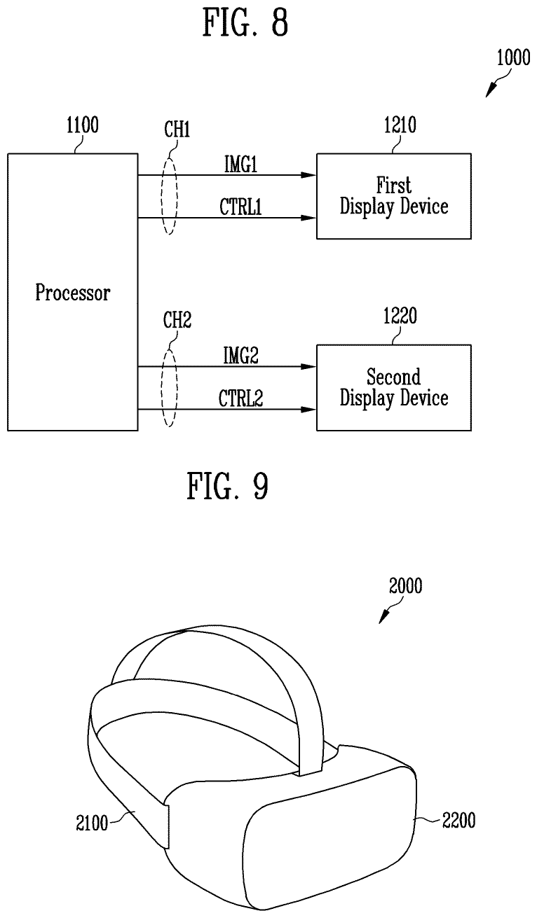

FIG. 8 is a block diagram of a display system according to one or more embodiments.

Referring to FIG. 8, the display system 1000 may include a processor 1100 and one or more display devices 1210 and 1220.

The processor 1100 may perform one or more suitable tasks and calculations. In one or more embodiments, the processor 1100 may include an application processor, a graphic processor, a microprocessor, a central processing unit (CPU), and/or the like. The processor 1100 may be connected to other components of the display system 1000 through a bus system and may control the other components.

In FIG. 8, the display system 1000 includes the first and second display devices 1210 and 1220. The processor 1100 may be connected to the first display device 1210 through a first channel CH1 and may be connected to the second display device 1220 through a second channel CH2.

Through the first channel CH1, the processor 1100 may be to transmit first image data IMG1 and a first control signal CTRL1 to the first display device 1210. The first display device 1210 may display an image based on the first image data IMG1 and the first control signal CTRL1. The first display device 1210 may be configured similarly to the display device 100 described with reference to FIG. 1. In this case, the first image data IMG1 and the first control signal CTRL1 may be provided as the input image data IMG and the control signal CTRL of FIG. 1, respectively.

Through the second channel CH2, the processor 1100 may be to transmit second image data IMG2 and a second control signal CTRL2 to the second display device 1220. The second display device 1220 may display an image based on the second image data IMG2 and the second control signal CTRL2. The second display device 1220 may have the same configuration as the display device 100 described with reference to FIG. 1. The second display device 1220 may be configured similarly to the display device 100 described with reference to FIG. 1. In this case, the second image data IMG2 and the second control signal CTRL2 may be provided as the input image data IMG and the control signal CTRL of FIG. 1, respectively.

The display system 1000 may include a computing system providing an image display function, such as a portable computer, a mobile phone, a smart phone, a tablet personal computer (PC), a smart watch, a watch phone, a portable multimedia player (PMP), a navigation device, and/or an ultra mobile personal computer (UMPC). In addition, the display system 1000 may include at least one selected from among a head mounted display (HMD) device, a virtual reality (VR) device, a mixed reality (MR) device, and an augmented reality (AR) device.

FIG. 9 is a perspective view of an application example of a display system of FIG. 8 according to one or more embodiments.

Referring to FIG. 9, the display system 1000 of FIG. 8 may be applied to a head mounted display device 2000. The head mounted display device 2000 may be a wearable electronic device that may be worn on a user's head.

The head mounted display device 2000 may include a head mount band 2100 and a display device receiving case 2200. The head mount band 2100 may be connected to the display device receiving case 2200. The head mount band 2100 may include a horizontal band and/or a vertical band for fixing the head mounted display device 2000 to the user's head. The horizontal band may be configured to be around (e.g., surround) a side portion of the user's head, and the vertical band may be configured to be around (e.g., surround) an upper portion of the user's head. However, embodiments are not limited thereto. For example, the head mount band 2100 may be implemented in the form of a glasses frame, a helmet, and/or the like.

The display device receiving case 2200 may receive the first and second display devices 1210 and 1220 of FIG. 8. The display device receiving case 2200 may further receive the processor 1100 of FIG. 8.

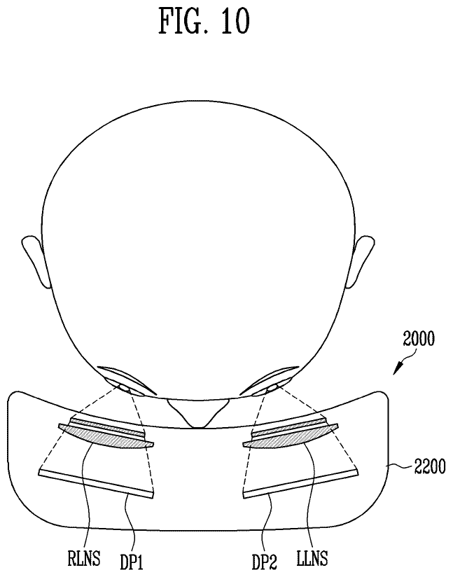

FIG. 10 is a diagram of a head-mounted display device of FIG. 9 that is worn on a user according to one or more embodiments.

Referring to FIG. 10, in a head mounted display device 2000, a first display panel DP1 of the first display device 1210 and a second display panel DP2 of the second display device 1220 are arranged. The head mounted display device 2000 may further include one or more lenses LLNS and RLNS.

Within the display device receiving case 2200, the right eye lens RLNS may be arranged between the first display panel DP1 and a user's right eye. Within the display device receiving case 2200, the left eye lens LLNS may be arranged between the second display panel DP2 and a user's left eye.

An image output from the first display panel DP1 may be displayed to the user's right eye through the right eye lens RLNS. The right eye lens RLNS may refract light from the first display panel DP1 to be directed toward the user's right eye. The right eye lens RLNS may perform an optical function for adjusting a viewing distance between the first display panel DP1 and the user's right eye.

An image output from the second display panel DP2 may be displayed to the user's left eye through the left eye lens LLNS. The left eye lens LLNS may refract light from the second display panel DP2 to be directed toward the user's left eye. The left eye lens LLNS may perform an optical function for adjusting a viewing distance between the second display panel DP2 and the user's left eye.

In one or more embodiments, each of the right eye lens RLNS and the left eye lens LLNS may include an optical lens having a pancake-shaped cross-section. In one or more embodiments, each of the right eye lens RLNS and the left eye lens LLNS may include a multi-channel lens including sub-areas having different optical characteristics. In this case, each display panel may output images respectively corresponding to the sub-areas of the multi-channel lens, and the output images may pass through the respective corresponding sub-areas and may be viewed by the user.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display manufacturing device, a display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Various embodiments of the present disclosure provide a light emitting element with an increased (e.g., improved) hole injection characteristic. Accordingly, color reproducibility and a display characteristic of a display device including the light emitting element may be increased (e.g., improved).

However, aspects and features of the present disclosure are not limited to those described above, and one or more suitable other aspects and features would be understood by one of ordinary skill in the art within the spirit and scope of the present disclosure.

The embodiments described in more detail above are provided to explain the present disclosure, but these embodiments are not intended to limit the scope of the present disclosure. It should be understood by those skilled in the art that one or more suitable changes, substitutions, and alternations may be made therein without departing from the scope of the disclosure as defined by the following claims and equivalents thereof.

The scope of embodiments according to the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of embodiments according to the present disclosure. The embodiments may be combined to form additional embodiments.

What is claimed is:

1. A light emitting element, comprising:
an anode;
a hole injection layer on the anode;
a hole transport layer on the hole injection layer;
a light emitting layer on the hole transport layer; and
a cathode on the light emitting layer,
wherein the hole injection layer comprises a triazine compound or a pyrimidine compound.

2. The light emitting element according to claim 1, wherein the hole injection layer contacts the anode.

3. The light emitting element according to claim 1, wherein a thickness of the hole injection layer is about 0.5 angstroms to 50 angstroms.

4. The light emitting element according to claim 1, wherein a dipole moment of the hole injection layer is about 1 Debye to 6 Debye.

5. The light emitting element according to claim 1, wherein a highest occupied molecular orbital (HOMO) energy level of the hole injection layer is about −6.3 eV to −5 eV.

6. The light emitting element according to claim 1, wherein the hole injection layer is a single layer.

7. The light emitting element according to claim 1, wherein
the anode is to provide a first hole and a second hole, and an energy barrier is between the anode and the hole injection layer,
the first hole being to cross over the energy barrier and transmit to the hole injection layer, and
the second hole being to pass through the energy barrier and transmit to the hole injection layer.

8. The light emitting element according to claim 1, further comprising:
an auxiliary layer between the hole transport layer and the light emitting layer.

9. The light emitting element according to claim 1, further comprising:
a buffer layer on the light emitting layer;
an electron transport layer on the buffer layer; and
an electron injection layer between the cathode and the electron transport layer.

10. A display device comprising:
a substrate;
a pixel circuit layer on the substrate; and
a light emitting element on the pixel circuit layer,
wherein the light emitting element comprises:
an anode on the pixel circuit layer;
a hole injection layer on the anode;
a hole transport layer on the hole injection layer;
a light emitting layer on the hole transport layer; and
a cathode on the light emitting layer,
wherein the hole injection layer comprises a triazine compound or a pyrimidine compound.

11. The display device according to claim 10, wherein
the substrate is a glass substrate, and
the anode is Ag/ITO.

12. The display device according to claim 10, wherein
the substrate is a silicon substrate, and
the anode is Al/TiN.

13. The display device according to claim 10, wherein the hole injection layer contacts the anode.

14. The display device according to claim 10, wherein a thickness of the hole injection layer is about 0.5 angstroms to 50 angstroms.

15. The display device according to claim 10, wherein a dipole moment of the hole injection layer is about 1 Debye to 6 Debye.

16. The display device according to claim 10, wherein a highest occupied molecular orbital (HOMO) energy level of the hole injection layer is about −6.3 eV to −5 eV.

17. The display device according to claim 10, wherein the hole injection layer is a single layer.

18. The display device according to claim 10, wherein
the anode is to provide a first hole and a second hole, and an energy barrier is between the anode and the hole injection layer,
the first hole being to cross over the energy barrier and transmit to the hole injection layer, and
the second hole being to pass through the energy barrier and transmit to the hole injection layer.

19. The display device according to claim 10, further comprising:
an auxiliary layer between the hole transport layer and the light emitting layer.

20. The display device according to claim 10, further comprising:
a buffer layer on the light emitting layer;
an electron transport layer on the buffer layer; and
an electron injection layer between the cathode and the electron transport layer.
